(19) United States
(12) Patent Application Publication
(10) Pub. No.: US 2012/0001041 A1
(43) Pub. Date: Jan. 5, 2012

(54) FIXING MECHANISM CAPABLE OF ADJUSTING A HANGING ANGLE OF AN ELECTRONIC DEVICE RELATIVE TO A POLE OR A SUPPORT WALL

(76) Inventors: Wan-Ru Yang, Taipei County (TW); Chih-Chan Chiang, Hsinchu County (TW); Kai-Tien Peng, Hsinchu County (TW)

(21) Appl. No.: 12/944,743

(22) Filed: Nov. 12, 2010

(30) Foreign Application Priority Data
Jul. 5, 2010 (TW) 099122016

(51) Int. Cl. H05K 7/14; F16M 13/02

(52) U.S. Cl. 248/219.4; 248/222.14

(57) ABSTRACT

A fixing mechanism includes a first bending plate, a second bending plate and a fixing part. The second bending plate is connected to the first bending plate at a bending angle. The second bending plate is used for screwing onto an electronic device with the first bending plate. The fixing part is detachably disposed through the first bending plate or the second bending plate to be disposed around a pole. The fixing part is used for clamping the pole with first tooth structures on the first bending plate or second tooth structures on the second bending plate. When the fixing part clamps the pole with the first tooth structures, the electronic device is substantially parallel to the pole. When the fixing part clamps the pole with the second tooth structures, an angle included between the electronic device and the pole is equal to a supplementary angle of the bending angle.

### BACKGROUND OF THE INVENTION

1. Field of the Invention

The present invention relates to a fixing mechanism, and more particularly, to a fixing mechanism capable of adjusting a hanging angle of an electronic device relative to a pole or a support wall.

2. Description of the Prior Art

Generally speaking, a conventional design for hanging an electronic device (e.g. a communication apparatus or a display device) on a pole is described as follows. First of all, the electronic device is fixed onto an L-shaped support plate in a screw-locking manner. Then, a tooth-shaped clip is disposed between the L-shaped support plate and the pole. Finally, a U-shaped pin is disposed through the L-shaped support plate in a screw-locking manner after sheathing the pole. Accordingly, the electronic device can be hung on the pole by utilizing the U-shaped pin and the tooth-shaped clip to clamp the pole tightly after the U-shaped fixing pin is tightly screwed onto the L-shaped plate.

However, the said design requires lots of parts, so as to result in a complicated assembly process. Thus, the said design causes a user great inconvenience in assembly. Moreover, the said design also lacks of flexibility in practical application since it cannot allow the user to adjust a hanging angle of the electronic device relative to the pole. In the prior art, the problem that the hanging angle of the electronic device is not adjustable can be solved by additional disposal of a link mechanism, but this design will cause a complicated hanging mechanism.

### SUMMARY OF THE INVENTION

According to one embodiment, the present invention provides a fixing mechanism capable of adjusting a hanging angle of an electronic device relative to a pole. The fixing mechanism includes a first bending plate, a second bending plate and a fixing part. The first bending plate has a plurality of first tooth structures, the second bending plate is connected to the first bending plate at a bending angle and has a plurality of second tooth structures, and the second bending plate is used for fixing to the electronic device with the first bending plate in a screw-locking manner. The fixing part is detachably disposed through the first bending plate or the second bending plate so as to be disposed around a pole, and the fixing part is used for clamping the pole with the plurality of first tooth structures or the plurality of second tooth structures. When the fixing part clamps the pole with the plurality of first tooth structures, the electronic device is substantially parallel to the pole. When the fixing part clamps the pole with the plurality of second tooth structures, an angle included between the electronic device and the pole is substantially equal to a supplementary angle of the bending angle.

According to another embodiment, the present invention provides a fixing mechanism capable of adjusting a hanging angle of an electronic device relative to a support wall. The fixing mechanism includes a first bending plate and a second bending plate. The second bending plate is connected to the first bending plate at a bending angle, and the second bending plate is used for fixing to the electronic device with the first bending plate in a screw-locking manner. When the first bending plate is fixed onto the support wall, the electronic device is hung parallel to the support wall. When the second bending plate is fixed onto the support wall, an angle included between the electronic device and the support wall is substantially equal to a supplementary angle of the bending angle.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an assembly diagram of a fixing mechanism according to a preferred embodiment of the present invention.

FIG. 2 is an exploded diagram of the fixing mechanism in FIG. 1.

FIG. 3 is an assembly diagram of the fixing mechanism in FIG. 2 being fixed onto a pole.

FIG. 4 is a side view of first tooth structures in FIG. 2 clamping the pole with a fixing part.

FIG. 5 is a side view of second tooth structures in FIG. 2 clamping the pole with the fixing part.

FIG. 6 is a side view of a first bending plate and a second bending plate in FIG. 2 clamping the pole with the fixing part after being rotated by 180°.

FIG. 7 is a diagram of a fixing mechanism according to another preferred embodiment of the present invention.

FIG. 8 is a side view of the fixing mechanism in FIG. 7 fixing an electronic device to a support wall.

### DETAILED DESCRIPTION

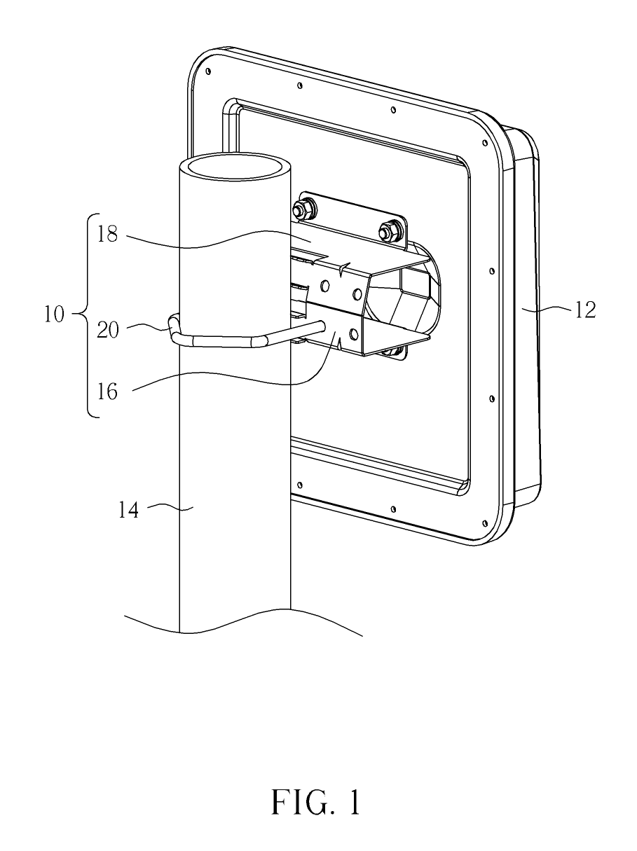

Please refer to FIG. 1, which is an assembly diagram of a fixing mechanism 10 according to a preferred embodiment of the present invention. As shown in FIG. 1, the fixing mechanism 10 is used for hanging an electronic device 12 on a pole 14. In this embodiment, the electronic device 12 can preferably be, but not limited to, a communication apparatus (e.g. a communication base station). It can also be other common electronic device, such as a display device. The pole 14 is a fixing pole used for hanging an object.

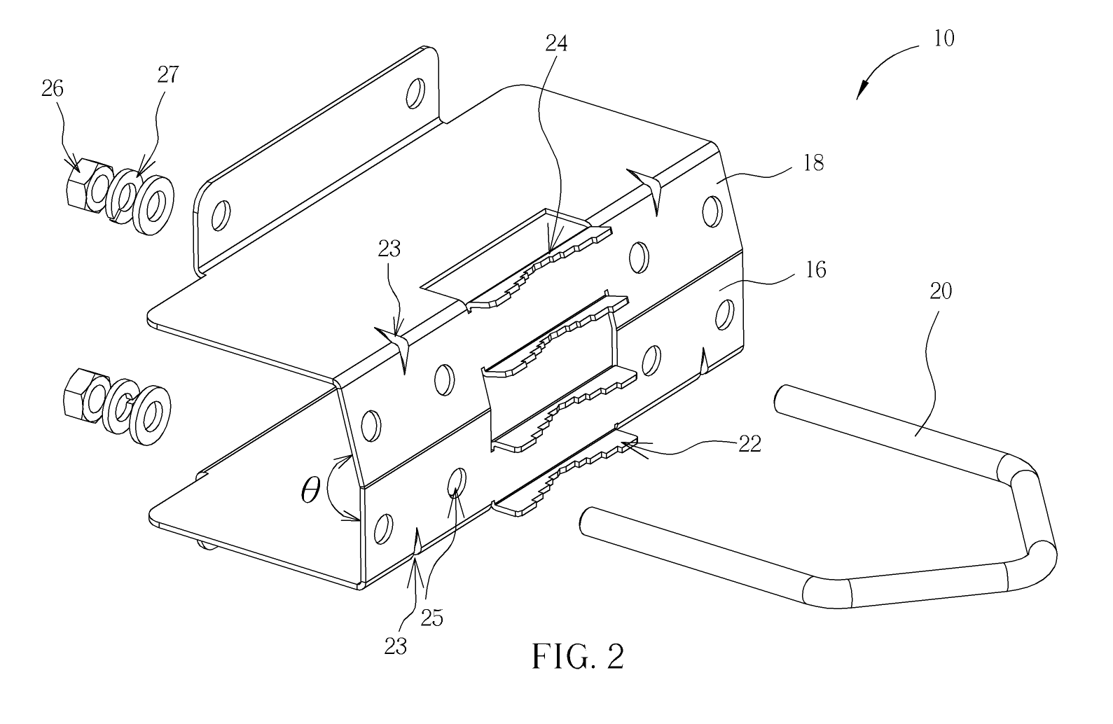

Hereinafter, the structural design of the fixing mechanism 10 will be illustrated. Please refer to FIG. 2, which is an exploded diagram of the fixing mechanism 10 in FIG. 1. As shown in FIG. 2, the fixing mechanism 10 includes a first bending plate 16, a second bending plate 18 and a fixing part 20. The first bending plate 16 is connected to the second bending plate 18 at a bending angle θ, wherein the bending angle θ is preferably, but not limited to, equal to 165°. In other words, as long as the electronic device 12 can be hung on the pole 14 by using the fixing mechanism 10, the bending angle included between the first bending plate 16 and the second bending plate 18 is variable depending on applications of the electronic device 12.

In this embodiment, the first bending plate 16 and the second bending plate 18 are formed as a U-shaped support frame by an integrally-forming method (such as a stamping process) for screwing onto the electronic device 12 as shown in FIG. 1. Furthermore, the first bending plate 16 and the second bending plate 18 have a plurality of first tooth structures 22 and a plurality of second tooth structures 24, respectively (two first tooth structures 22 and two second tooth structures 24 shown in FIG. 2). In other words, the plurality of first tooth structures 22 and the plurality of second tooth structures 24 are not independent parts, but structures integrally formed on the first bending plate 16 and the second bending plate 18 by a conventional machining method (such as a stamping process). The related description for the machining method is omitted herein since it is commonly seen in the prior art. At least one rib structure 23 (two shown in FIG. 2) is formed on a bending position of the first bending plate 16 and that of the second bending plate 18 respectively, so as to enhance the structural strength of the first bending plate 16 and the second bending plate 18. The rib structure 23 can be an omissible part so as to simplify the structural design of the fixing mechanism 10. As for whether disposal of the rib structure 23 is adopted or not, it depends on requirement of the fixing mechanism 10 in practical application. Forming of the rib structure 23 can be achieved by a conventional machining method, such as a punching process.

The fixing part 20 of the fixing mechanism 10 is preferably a U-shaped pin, which can be detachably disposed through the first bending plate 16 or through the second bending plate 18 via positioning holes 25 formed on the first bending plate 16 and on the second bending plate 18. Accordingly, the fixing part 20 can clamp the pole 14 with the plurality of first tooth structures 22 or with the plurality of second tooth structures 24, wherein the screw-locking between the fixing part 20 and the first bending plate 16 or between the fixing part 20 and the second bending plate 18 can be achieved by screws 26 and washers 27 as shown in FIG. 2. Number of the positioning hole 25 formed on the first bending plate 16 or the second bending plate 18 is not limited to two sets as shown in FIG. 2. It varies with sizes of poles that the fixing mechanism 10 is desired to fix to, so as to achieve the purpose that the electronic device 12 can be hung on the poles with different sizes by using the fixing parts with different sizes. In such a manner, flexibility of the fixing mechanism 10 in practical application can be further increased.

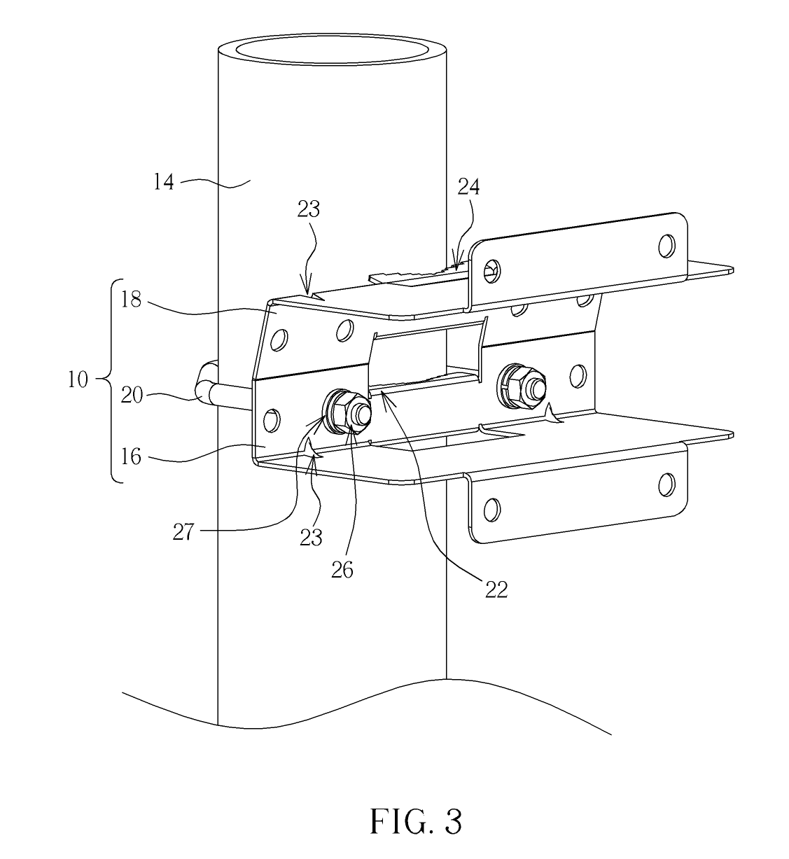

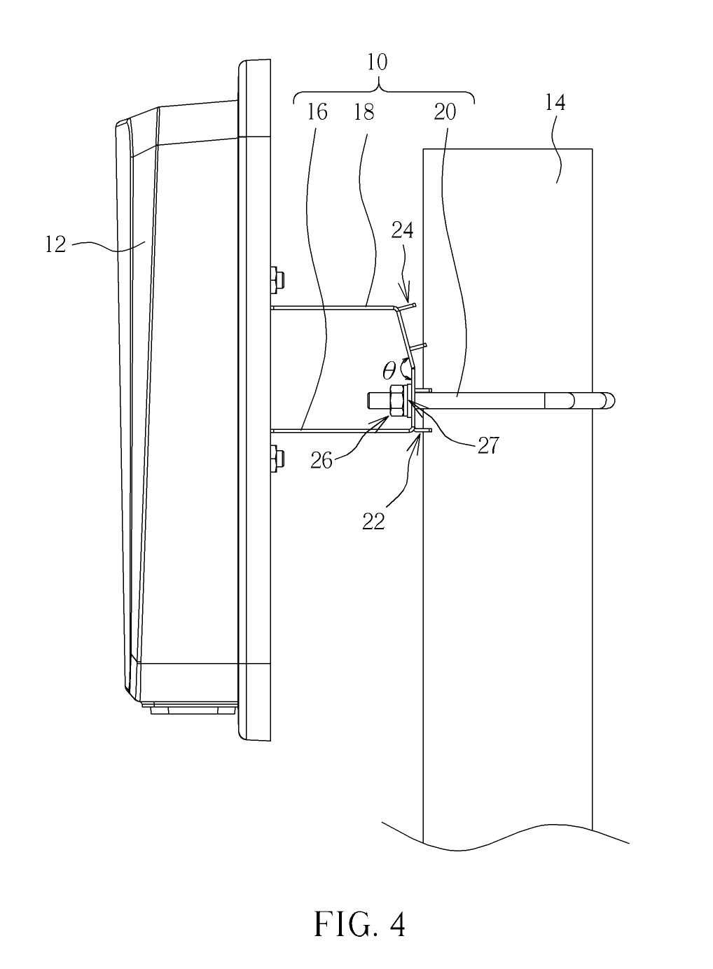

More detailed description for assembly of the fixing mechanism 10, the electronic device 12 and the pole 14 is provided as follows on condition that the electronic device 12 is a communication apparatus. Please refer to FIG. 3 and FIG. 4. FIG. 3 is an assembly diagram of the fixing mechanism 10 in FIG. 2 being fixed onto the pole 14. FIG. 4 is a side view of the first tooth structures 22 in FIG. 2 clamping the pole 14 with the fixing part 20. First of all, after sheathing the pole 14, two ends of the fixing part 20 can be disposed through the first bending plate 16, respectively. Then, the two ends of the fixing part 20 can be screwed onto the first bending plate 16 by using the screws 26 and the washers 27. In such a manner, the first tooth structures 22 on the first bending plate 16 can tightly clamp the pole 14 with the fixing part 20 as shown in FIG. 3. Finally, after the electronic device 12 is screwed onto the first bending plate 16 and the second bending plate 18, assembly of the fixing mechanism 10, the electronic device 12 and the pole 14 is completed accordingly, wherein the electronic device 12 can be hung parallel to the pole 14. It should be noticed that, as shown in FIG. 1 and FIG. 4, the second tooth structure 24 adjacent to the first tooth structures 22 may simultaneously abut against the pole 14 by the bending design of the first bending plate 16 and the second bending plate 18 when the first tooth structures 22 clamp the pole 14 with the fixing part 20, so as to increase clamping force applied on the pole 14 by the fixing mechanism 10.

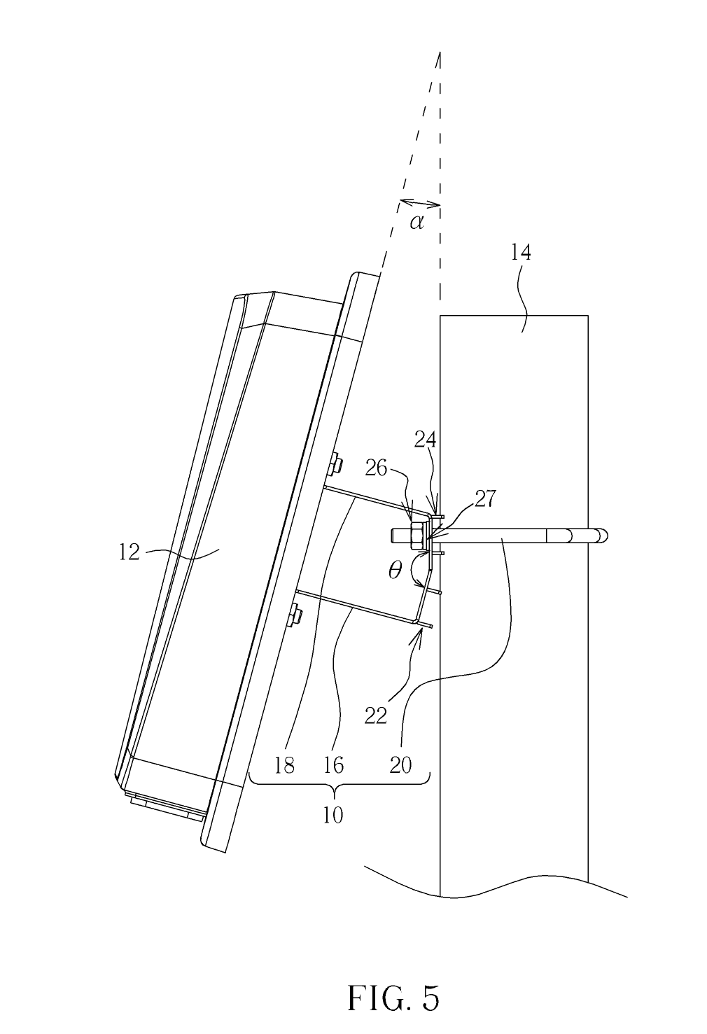

On the other hand, if a user wants to adjust a hanging angle of the electronic device 12 relative to the pole 14 for improving transmission quality of signals of the electronic device 12, the user just needs to dispose the two ends of the fixing part 20 through the second bending part 18 instead after the pole 14 is sheathed by the fixing part 20. Then, the user can utilize the screws 26 and the washers 27 to screw the two ends of the fixing part 20 onto the second bending plate 18. Accordingly, the second tooth structures 24 on the second bending plate 18 can tightly clamp the pole 14 with the fixing part 20 by screw-locking between the fixing part 20 and the second bending plate 18. Finally, after the electronic device 12 is screwed onto the first bending plate 16 and the second bending plate 18, assembly of the fixing mechanism 10, the electronic device 12 and the pole 14 is completed accordingly. At this time, the structural relationship among the fixing mechanism 10, the electronic device 12 and the pole 14 is as shown in FIG. 5, which is a side view of the second tooth structures 24 in FIG. 2 clamping the pole 14 with the fixing part 20. In other words, when the fixing mechanism 10 hangs the electronic device 12 on the pole 14 in a manner of the second tooth structures 24 clamping the pole 14 with the fixing part 20, the electronic device 12 is hung on the pole 14 at an upward tilt angle α. As shown in FIG. 5, the upward tilt angle α is substantially equal to a supplementary angle of the bending angle θ. In this embodiment, the bending angle θ is substantially equal to 165°, meaning that the electronic device 12 will be hung on the pole 14 at an upward tilt angle of 15°. Similarly, as shown in FIG. 5, when the second tooth structures 24 clamp the pole 14 with the fixing part 20, the first tooth structure 22 adjacent to the second tooth structures 24 can also abut against the pole 14 by the bending design of the first bending plate 16 and the second bending plate 18, so as to increase clamping force applied on the pole 14 by the fixing mechanism 10.

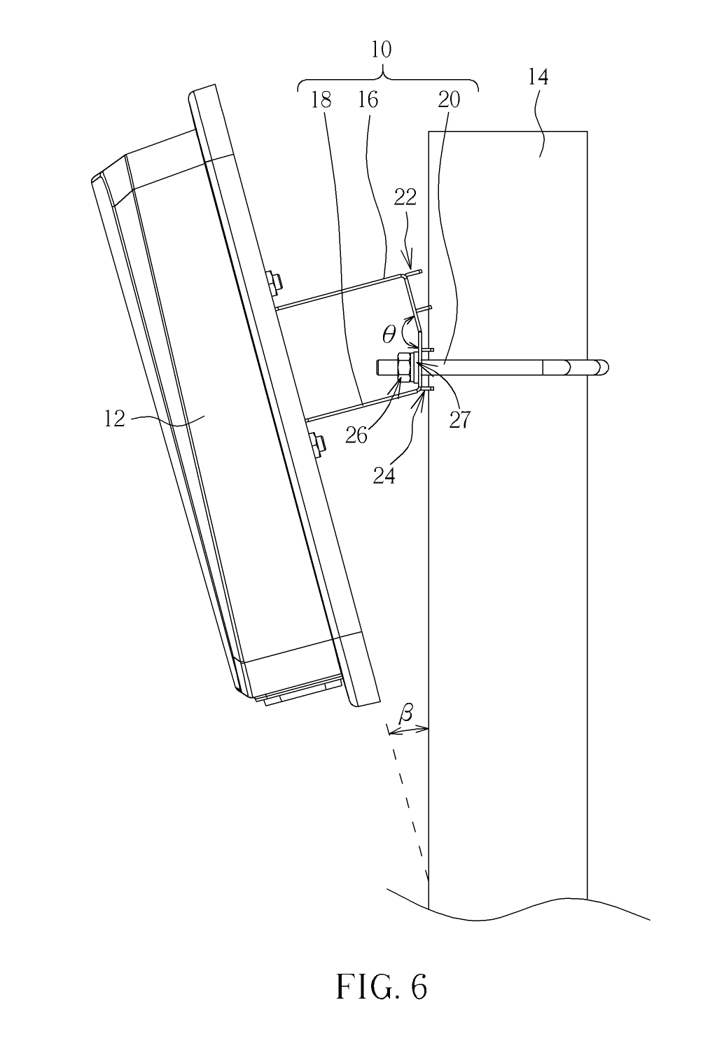

Furthermore, during the said assembly process, if a support frame formed by the first bending plate 16 and the second bending plate 18 is rotated by 180°, the two ends of the fixing part 20 are disposed through the second bending plate 18, and then the subsequent assembly steps are performed according to the said assembly process, the structural relationship among the fixing mechanism 10, the electronic device 12 and the pole 14 will be as shown in FIG. 6. FIG. 6 is a side view of the first bending plate 16 and the second bending plate 18 in FIG. 2 clamping the pole 14 with the fixing part 20 after being rotated by 180°. In other words, when the fixing mechanism 10 is hung on the pole 14 according to the said assembly process after the support frame formed by the first bending plate 16 and the second bending plate 18 in FIG. 2 is rotated by 180°, the electronic device 12 will be hung on the pole 14 at a downward tilt angle β. As shown in FIG. 6, the downward tilt angle β is substantially equal to the supplementary angle of the bending angle θ. In this embodiment, the bending angle θ is substantially equal to 165°, meaning that the electronic device 12 will be hung on the pole 14 at a downward tilt angle of 15°. Similarly, as shown in FIG. 6, the first tooth structure 22 adjacent to the second tooth structures 24 can also abut against the pole 14 by the bending design of the first bending plate 16 and the second bending plate 18 when the second tooth structures 24 clamp the pole 14 with the fixing part 20, so as to increase clamping force applied on the pole 14 by the fixing mechanism 10.

In summary, the hanging angle of the electronic device 12 relative to the pole 14 can be adjustable by the bending design of the first bending plate 16 and the second bending plate 18 and by the said assembly process of selectively utilizing the first tooth structures 22 of the first bending plate 16 or the second tooth structures 24 of the second bending plate 18 to clamp the pole 14 with the fixing part 20. For example, according to the said assembly process in this embodiment, the electronic device 12 can be hung selectively parallel to the pole 14, on the pole 14 at an upward tilt angle of 15° or on the pole 14 at a downward tilt angle of 15°.

It should be mentioned that the structural design of the fixing part 20 is not limited to the said embodiment. In other words, all other structures having the same fixing effect as that of the U-shaped pin (i.e. fixing structures capable of clamping the pole 14 with the first tooth structures 22 or the second tooth structures 24 after being disposed through the first bending plate 16 or the second bending plate 18) may fall within the scope of the present invention. For example, the fixing part 20 can be a ring-shaped locking belt instead. After the ring-shaped locking belt is disposed through the first bending plate 16 or the second bending plate 18, the first bending plate 16 or the second bending plate 18 can be tied tightly on the pole 14 by the ring-shaped locking belt in a manner of screwing two ends of the ring-shaped locking belt tightly at another side of the pole 14 opposite to the electronic device 12.

Furthermore, except for using the fixing mechanism 10 to hang the electronic device 12 on the pole 14, the user can also screw the first bending plate 16 or the second bending plate 18 on a support wall after the fixing part 20 is detached from the first bending plate 16 or the second bending plate 18, so as to make the electronic device 12 hung parallel to the support wall or on the support wall at a hanging angle equal to a supplementary angle of the bending angle θ. Accordingly, the fixing mechanism 10 can be more flexible in use. It should be noticed that when the fixing mechanism 10 is used for hanging the electronic device 12 on the support wall, the plurality of first tooth structures 22 is preferably recessed from the first bending plate 16. Similarly, the plurality of second tooth structures 24 is preferably recessed from the second bending plate 18. Accordingly, during the process of screwing the first bending plate 16 or the second bending plate 18 onto the support wall, the problem that the first bending plate 16 or the second bending plate 18 cannot be fixed to the support wall due to protrusion of the first tooth structures 22 or the second tooth structures 24 as shown in FIG. 2 can be solved. Furthermore, in this condition, the first bending plate 16 and the second bending plate 18 can also be lengthened, so as to make the user screw the electronic device 12 with the first bending plate 16 and the second bending plate 18 more conveniently.

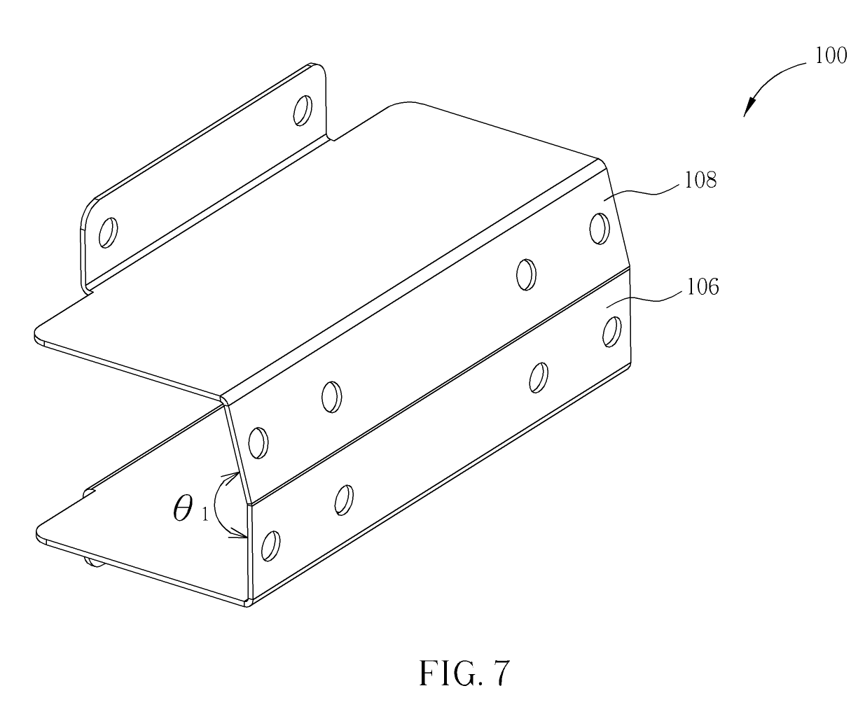

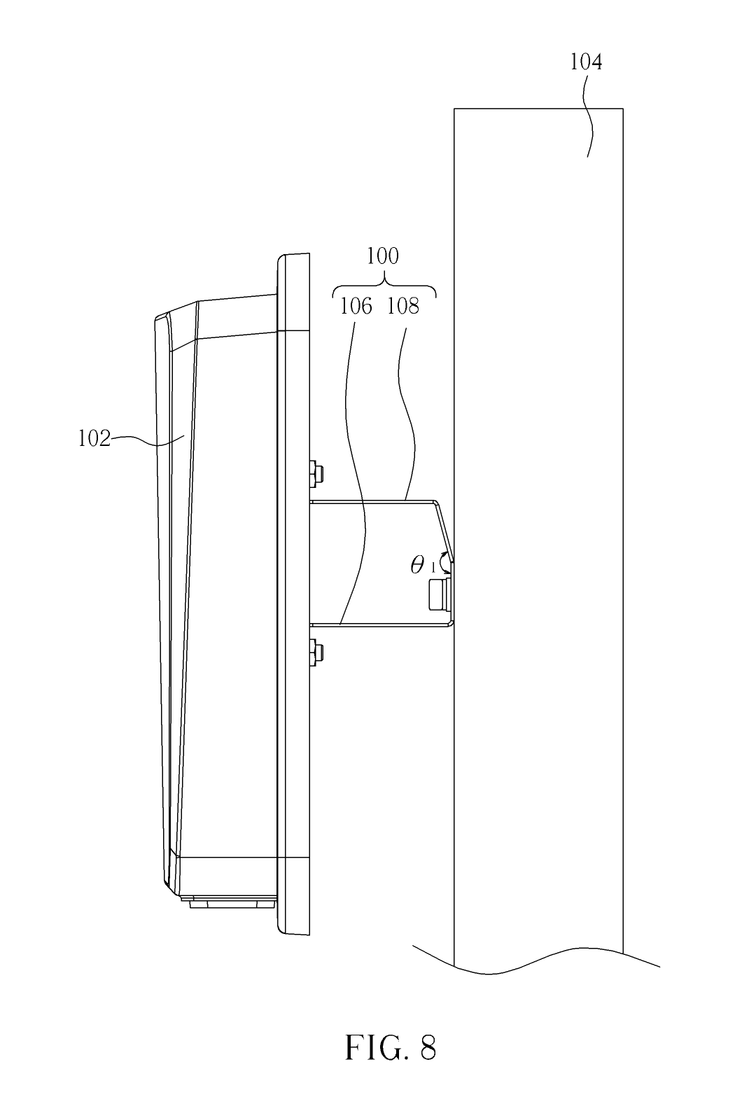

Next, please refer to FIG. 7 and FIG. 8. FIG. 7 is a diagram of a fixing mechanism 100 according to another preferred embodiment of the present invention. FIG. 8 is a side view of the fixing mechanism 100 in FIG. 7 fixing an electronic device 102 onto a support wall 104. As shown in FIG. 7, the fixing mechanism 100 includes a first bending plate 106 and a second bending plate 108. The second bending plate 108 is connected to the first bending plate 106 at a bending angle θ₁, wherein θ₁ is preferably, but not limited to, equal to 165°. In other words, as long as the electronic device 102 can be hung on the support wall 104 by using the fixing mechanism 100, the bending angle included between the first bending plate 106 and the second bending plate 108 is variable depending on applications of the electronic device 102.

More detailed description for assembly of the fixing mechanism 100, the electronic device 102 and the pole 104 is provided as follows on condition that the electronic device 102 is a communication apparatus. Please refer to FIG. 7 and FIG. 8. First of all, the electronic device 102 needs to be screwed onto the first bending plate 106 and the second bending plate 108. Then, after the first bending plate 106 is screwed onto the support wall 104, assembly of the fixing mechanism 100, the electronic device 102 and the pole 104 is completed accordingly, wherein the electronic device 12 is hung substantially parallel to the support wall 104.

On the other hand, if the user wants to adjust a hanging angle of the electronic device 102 relative to the support wall 104 for improving transmission quality of signals of the electronic device 102, the user just needs to perform the said assembly process mentioned in the said embodiment so that the hanging angle of the electronic device 102 relative to the support wall 104 can be changed accordingly. For example, if the bending angle θ₁ is equal to 165°, by screwing the second bending plate 108 onto the support wall 104 or by screwing the second bending plate 108 onto the support wall 104 after rotating the fixing mechanism 100 in FIG. 7 by 180°, the electronic device 102 can be hung on the support wall 104 at an upward tilt angle of 15° or at a downward tilt angle of 15°.

It should be mentioned that the structural designs mentioned in the said embodiment can be applied in this embodiment so as to increase flexibility of the fixing mechanism 100 in practical application, such as assembly of the fixing part and the tooth structures, the recessed design of the tooth structure, additional disposal of the rib structure, and number variation of the positioning hole. The related description for the said structural designs is omitted herein since it has been mentioned in the said embodiment.

Compared with the prior art, the present invention utilizes the tooth structures integrally formed on the bending plates and the bending design on the fixing mechanism to reduce part number of the fixing mechanism and achieve the purpose that a hanging angle of an electronic device relative to a pole or a support wall is adjustable. In such a manner, the assembly process of the electronic device being hung on the pole or on the support wall will be simplified greatly. Furthermore, the fixing mechanism of the present invention can meet different use needs in different cases since the fixing mechanism provided by the present invention can allow the user to hang the electronic device onto the pole (or the support wall) in a manner of being parallel to the pole, being tilted upward relative to the pole or being tilted downward relative to the pole according to the assembly processes mentioned in the said embodiments. Accordingly, flexibility and use convenience of the fixing mechanism can be further increased in practical application.

Those skilled in the art will readily observe that numerous modifications and alterations of the device and method may be made while retaining the teachings of the invention.

What is claimed is:

1. A fixing mechanism capable of adjusting a hanging angle of an electronic device relative to a pole, the fixing mechanism comprising:
a first bending plate having a plurality of first tooth structures;
a second bending plate connected to the first bending plate at a bending angle and having a plurality of second tooth structures, the second bending plate being used for fixing to the electronic device with the first bending plate in a screw-locking manner; and
a fixing part detachably disposed through the first bending plate or the second bending plate so as to be disposed around a pole, the fixing part being used for clamping the pole with the plurality of first tooth structures or the plurality of second tooth structures;
wherein the electronic device is substantially parallel to the pole when the fixing part clamps the pole with the plurality of first tooth structures, and an angle included between the electronic device and the pole is substantially equal to a supplementary angle of the bending angle when the fixing part clamps the pole with the plurality of second tooth structures.

2. The fixing mechanism of claim 1, wherein the bending angle is substantially equal to 165°.

3. The fixing mechanism of claim 1, wherein the fixing part is a U-shaped pin fixed to the first bending plate or to the second bending plate in a screw-locking manner.

4. The fixing mechanism of claim 1, wherein the fixing part is a ring-shaped locking belt tightly tied on the pole in a screw-locking manner after disposing through the first bending plate or the second bending plate.

5. The fixing mechanism of claim 1, wherein the first bending plate is fixed onto a support wall in a screw-locking manner after the fixing part is detached from the first bending plate, so as to make the electronic device be hung parallel to the support wall.

6. The fixing mechanism of claim 5, wherein the plurality of first tooth structures is recessed from the first bending plate.

7. The fixing mechanism of claim 1, wherein the second bending plate is fixed on a support wall in a screw-locking manner after the fixing part is detached from the second bending plate, so as to make the electronic device be hung on the support wall at the supplementary angle of the bending angle.

8. The fixing mechanism of claim 7, wherein the plurality of second tooth structures is recessed from the second bending plate.

9. The fixing mechanism of claim 1, wherein at least one rib structure is formed at a bending position of the first bending plate or the second bending plate.

10. A fixing mechanism capable of adjusting a hanging angle of an electronic device relative to a support wall, the fixing mechanism comprising:
a first bending plate; and
a second bending plate connected to the first bending plate at a bending angle, the second bending plate being used for fixing to the electronic device with the first bending plate in a screw-locking manner;
wherein the electronic device is hung parallel to the support wall when the first bending plate is fixed onto the support wall, and an angle included between the electronic device and the support wall is substantially equal to a supplementary angle of the bending angle when the second bending plate is fixed onto the support wall.

11. The fixing mechanism of claim 10, wherein the bending angle is substantially equal to 165°.

12. The fixing mechanism of claim 10, wherein the first bending plate has a plurality of first tooth structures, the plurality of first tooth structures is used for clamping a pole with a fixing part so as to make the electronic device substantially parallel to the pole, the second bending plate has a plurality of second tooth structures, and the plurality of second tooth structures is used for clamping the pole with the fixing part so as to make an angle included between the electronic device and the pole substantially equal to the supplementary angle of the bending angle.

13. The fixing mechanism of claim 12, wherein the plurality of first tooth structures is recessed from the first bending plate, and plurality of second tooth structures is recessed from the second bending plate.
